(19) United States
(12) Patent Application Publication
(10) Pub. No.: US 2023/0131985 A1
(43) Pub. Date: Apr. 27, 2023

(54) TRANSPARENT CONDUCTIVE LAYER AND TRANSPARENT CONDUCTIVE SHEET

(71) Applicant: NITTO DENKO CORPORATION, Ibaraki-shi, Osaka (JP)

(72) Inventors: Nozomi Fujino, Osaka (JP); Taisuke Karasuda, Osaka (JP)

(73) Assignee: NITTO DENKO CORPORATION, Ibaraki-shi, Osaka (JP)

(21) Appl. No.: 17/912,196

(22) PCT Filed: Mar. 18, 2021
(86) PCT No.: PCT/JP2021/011166

§ 371 Date: Sep. 16, 2022

(30) Foreign Application Priority Data
Mar. 19, 2020 (JP) 2020-049864
Apr. 20, 2020 (JP) 2020-074853
Apr. 20, 2020 (JP) 2020-074854
Aug. 7, 2020 (JP) 2020-134832
Aug. 7, 2020 (JP) 2020-134833
Aug. 21, 2020 (JP) 2020-140238
Aug. 21, 2020 (JP) 2020-140239
Aug. 21, 2020 (JP) 2020-140240
Aug. 21, 2020 (JP) 2020-140241
Sep. 4, 2020 (JP) 2020-149474
Oct. 29, 2020 (JP) 2020-181349
Dec. 2, 2020 (JP) 2020-200421
Dec. 2, 2020 (JP) 2020-200422

(51) Int. Cl. H01B 5/14; H01B 1/08; C23C 14/00; C23C 14/35; C23C 14/58

(52) U.S. Cl. CPC H01B 5/14; H01B 1/08; C23C 14/0057; C23C 14/35; C23C 14/5806

(57) ABSTRACT

The transparent conductive layer (3) includes a first main surface (5), and a second main surface (6) opposed to the first main surface (5) in a thickness direction. The transparent conductive layer (3) has a first grain boundary (7) in which two end edges (23) in a cross-sectional view are both opened to the first main surface (5) and an intermediate region (25) between the end edges (23) is not in contact with the second main surface (6); and a first crystal grain (31) partitioned by the first grain boundary (7) and facing only the first main surface (5). The transparent conductive layer (3) contains rare gas atoms having a higher atomic number than argon atoms.

### TECHNICAL FIELD

The present invention relates to a transparent conductive layer and a transparent conductive sheet.

### BACKGROUND ART

Conventionally, a transparent conductive sheet including a crystalline transparent conductive layer has been known.

For example, a light-transmitting electrically conductive film including a light-transmitting electrically conductive layer having a plurality of crystal grains has been proposed (see, for example, the following Patent Document 1).

In the light-transmitting electrically conductive layer described in Patent Document 1, grain boundaries partitioning the plurality of crystal grains described above are present from the upper surface to the lower surface of the light-transmitting electrically conductive layer.

The light-transmitting electrically conductive layer of Patent Document 1 can also be formed into a wiring pattern by etching.

### CITATION LIST

### Patent Document

Patent Document 1: Japanese Unexamined Patent Publication No. 2018-41059

### SUMMARY OF THE INVENTION

### Problem to be Solved by the Invention

The light-transmitting electrically conductive layer may be etched because of formation of wiring pattern, designability, or the like. In recent years, the light-transmitting electrically conductive layer is required to have a high etching rate in order to improve productivity of the etching process. However, the light-transmitting electrically conductive layer described in Patent Document 1 disadvantageously fails to meet the above-mentioned requirement.

Further, this light-transmitting electrically conductive layer is required to have a low resistance.

The present invention provides a transparent conductive layer and a transparent conductive sheet having a low resistance and a high etching rate.

### Means for Solving the Problem

The present invention [1] includes a transparent conductive layer that includes a first main surface; and a second main surface opposed to the first main surface in a thickness direction, has a grain boundary in which two end edges in a cross-sectional view are both opened to the first main surface and an intermediate region between the end edges is not in contact with the second main surface; and a first crystal grain partitioned by the grain boundary and facing only the first main surface, and contains rare gas atoms having a higher atomic number than argon atoms.

The present invention [2] includes the transparent conductive layer described in claim 1 including a region of a single layer extending in a plane direction orthogonal to the thickness direction.

The present invention [3] includes the transparent conductive layer described in [1] or [2], further having a second grain boundary opened to a side surface that connects one end edge of the first main surface and one end edge of the second main surface.

The present invention [4] includes the transparent conductive layer described in any one of the above-described [1] to [3], in which a material of the transparent conductive layer is a tin-containing oxide.

The present invention [5] includes a transparent conductive sheet including a transparent conductive layer described in any one of the above-described [1] to [4]; and a substrate layer located on a side of the second main surface of the transparent conductive layer.

### Effects of the Invention

The transparent conductive layer of the present invention has a grain boundary in which two end edges in a cross-sectional view are both opened to the first main surface and an intermediate region between the end edges is not in contact with the second main surface; and a first crystal grain partitioned by the grain boundary and facing only the first main surface.

In the transparent conductive layer, when an etchant comes in contact with the first main surface, the etchant easily penetrates into the grain boundary from the two end edges. Therefore, the first crystal grain partitioned by this grain boundary is easily peeled off. This results in high etching rate of the transparent conductive layer.

The transparent conductive layer contains rare gas atoms having a higher atomic number than argon atoms. Specifically, when the transparent conductive layer is produced by a sputtering method, atoms derived from a sputtering gas are incorporated into the transparent conductive layer. These atoms derived from the sputtering gas inhibit crystallization of the transparent conductive layer. This results in an increase in the specific resistance of the transparent conductive layer.

Meanwhile, the transparent conductive layer is obtained using a rare gas having a higher atomic number than argon atoms as the sputtering gas. Since the rare gas having a higher atomic number than argon atoms has a high atomic weight, incorporation of atoms derived from the rare gas having a higher atomic number than argon atoms into the transparent conductive layer can be suppressed. That is, although the transparent conductive layer contains the atoms derived from the rare gas having a higher atomic number than argon atoms, the amount thereof is suppressed as described above. Therefore, the atoms derived from the rare gas having a higher atomic number than argon atoms can prevent crystallization of the transparent conductive layer from being inhibited. As a result of this, the specific resistance of the transparent conductive layer can be reduced.

The transparent conductive sheet of the present invention includes the transparent conductive layer of the present invention. Therefore, the transparent conductive sheet has a low resistance and a high etching rate.

### BRIEF DESCRIPTION OF THE DRAWINGS

FIG. 1 is a schematic view showing one embodiment of a transparent conductive layer and a transparent conductive sheet according to the present invention.

FIG. 2 is a cross-sectional view of the transparent conductive layer in the transparent conductive sheet shown in FIG. 1.

FIG. 3 is a schematic view showing one embodiment of a method for producing the transparent conductive layer and the transparent conductive sheet according to the present invention. FIG. 3A shows a step of preparing a transparent substrate in a first step. FIG. 3B shows a step of disposing a hard coat layer on one surface of the transparent substrate in a thickness direction in the first step. FIG. 3C shows a second step of disposing the transparent conductive layer on one surface of a substrate layer in the thickness direction. FIG. 3D shows a third step of heating the transparent conductive layer.

FIG. 4 is a graph showing a relationship between a specific resistance of an amorphous transparent conductive layer and an amount of oxygen introduced.

FIG. 5 shows a schematic view of a modification of the transparent conductive layer according to the present invention, the modification in which a fourth crystal grain is partitioned by two third grain boundaries.

FIG. 6 shows a schematic view of a modification of the transparent conductive layer according to the present invention, the modification in which a fifth crystal grain not facing any of a first main surface, a second main surface, and a side surface is included.

FIG. 7 shows a schematic view of a modification of the transparent conductive layer according to the present invention, the modification in which a first grain boundary does not include a branch point.

FIG. 8 shows a schematic view of a modification of the transparent conductive sheet according to the present invention, the modification in which a first rare gas atom-free transparent conductive layer is provided.

### DESCRIPTION OF THE EMBODIMENTS

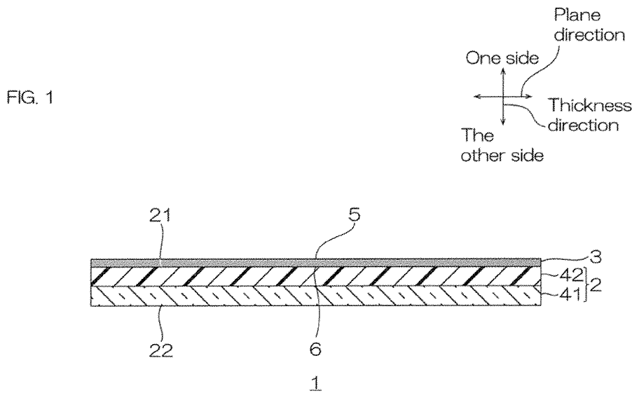

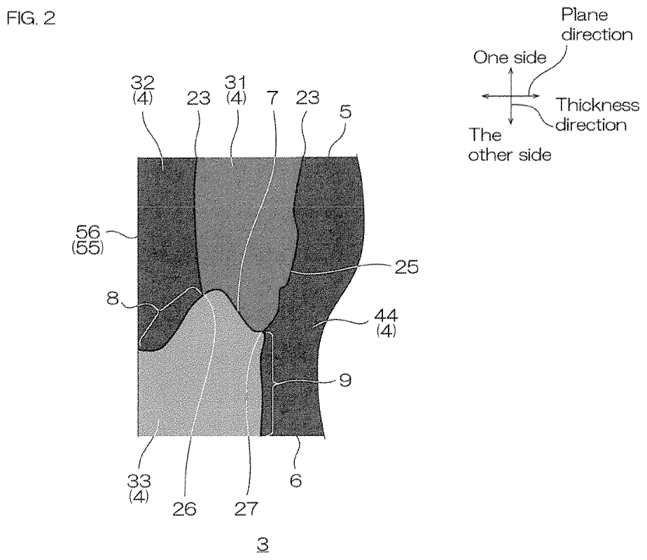

Embodiments of the transparent conductive layer and the transparent conductive sheet according to the present invention will be described with reference to FIGS. 1 and 2. In FIG. 2, a plurality of crystal grains 4 (described later) are clearly shown, and are drawn in gray colors having different concentrations in order to distinguish between a first grain boundary 7 (described later) to a third grain boundary 9 (described later), and a leader line and a phantom line segment (dashed line).

### <Transparent Conductive Sheet>

As shown in FIG. 1, the transparent conductive sheet 1 has a predetermined thickness and has a sheet shape extending in a plane direction orthogonal to the thickness direction. The transparent conductive sheet 1 sequentially includes a substrate layer 2, and a transparent conductive layer 3 toward one side in the thickness direction. To be specific, the transparent conductive sheet 1 includes a substrate layer 2, and a transparent conductive layer 3 disposed on one surface of the substrate layer 2 in the thickness direction.

### <Substrate Layer>

The substrate layer 2 is a transparent substrate for ensuring mechanical strength of the transparent conductive sheet 1. The substrate layer 2 extends in the plane direction. The substrate layer 2 has a substrate first main surface 21 and a substrate second main surface 22. The substrate first main surface 21 is a flat surface. The substrate second main surface 22 is opposed at a spaced interval to the substrate first main surface 21 on the other side in the thickness direction. The substrate layer 2 is located on the side of a second main surface 6 (described later) of the transparent conductive layer 3. The substrate second main surface 22 is parallel to the substrate first main surface 21.

The flat surface may or may not include whether the first main surface 21 of the substrate layer 2 and the second main surface 22 of the substrate layer 2 are planes substantially in parallel to each other. For example, unevenness and waving that are too fine to be observed are allowed.

The substrate layer 2 includes a transparent substrate 41 and a functional layer 42.

To be specific, the substrate layer 2 sequentially includes a transparent substrate 41 and a functional layer 42 toward one side in the thickness direction. To be specific, the substrate layer 2 includes a transparent substrate 41, and a functional layer 42 disposed on one surface of the transparent substrate 41 in the thickness direction.

### <Transparent Substrate>

The transparent substrate 41 has a film-like shape.

Examples of a material of the transparent substrate 41 include olefine resin, polyester resin, (meth)acrylic resin (acrylic resin and/or methacrylic resin), polycarbonate resin, polyether sulfone resin, polyarylate resin, melamine resin, polyamide resin, polyimide resin, cellulose resin, and polystyrene resin. Examples of the olefin resin include polyethylene, polypropylene, and cycloolefin polymer. Examples of the polyester resin include polyethylene terephthalate (PET), polybutylene terephthalate, and polyethylene naphthalate. Examples of the (meth)acrylic resin include polymethacrylate. As the material of the transparent substrate 41, preferably, a polyester resin is used, more preferably, a polyethylene terephthalate (PET) is used, in view of transparency and resistance to moisture permeability.

The transparent substrate 41 has transparency. To be specific, the transparent substrate 41 has a total light transmittance (JIS K 7375-2008) of, for example, 60% or more, preferably 80% or more, more preferably 85% or more.

The transparent substrate 41 has a thickness of, for example, 1 μm or more, preferably 10 μm or more, preferably 30 μm or more, and for example, 1000 μm or less, preferably 500 μm or less, more preferably 250 μm or less, even more preferably 200 μm or less, particularly preferably 100 μm or less, most preferably 60 μm or less.

### <Functional Layer>

The functional layer 42 is disposed on one surface of the transparent substrate 41 in the thickness direction.

The functional layer 42 has a film-like shape.

Examples of the functional layer 42 include a hard coat layer.

In this case, the substrate layer 2 sequentially includes the transparent substrate 41 and a hard coat layer toward one side in the thickness direction.

The following will describe a case where the functional layer 42 is a hard coat layer.

The hard coat layer is a protective layer for preventing the transparent conductive sheet 1 from being scratched.

The hard coat layer is formed of, for example, a hard coat composition.

The hard coat composition contains a resin and, as needed, particles. That is, the hard coat layer contains a resin and, as needed, particles.

Examples of the resin include a thermoplastic resin and a curable resin. Examples of the thermoplastic resin include a polyolefin resin.

Examples of the curable resin include an active energy ray-curable resin that is cured by irradiation with an active energy ray (e.g., ultraviolet ray and electron beam) and a thermosetting resin that is cured by heating. As the curable resin, preferably, an active energy ray-curable resin is used.

Examples of the active energy ray-curable resin include an ultraviolet curable (meth)acrylic resin, a urethane resin, a melamine resin, an alkyd resin, a siloxane polymer, and an organic silane condensate. As the active energy ray-curable resin, preferably, an ultraviolet curable (meth)acrylic resin is used.

The resin can contain a reactive diluent described in, for example, Japanese Unexamined Patent Publication No. 2008-88309. To be specific, the resin can contain polyfunctional (meth)acrylate.

The resin can be used alone or in combination of two or more kinds.

Examples of the particles include metal oxide fine particles and organic fine particles. Examples of a material of the metal oxide fine particles include silica, alumina, titania, zirconia, calcium oxide, tin oxide, indium oxide, cadmium oxide, and antimony oxide. Examples of a material of the organic fine particles include polymethyl methacrylate, silicone, polystyrene, polyurethane, acryl-styrene copolymer, benzoguanamine, melamine, and polycarbonate.

The particles can be used alone or in combination of two or more kinds.

The hard coat composition can be mixed with a thixotropy-imparting agent, a photopolymerization initiator, a filler (e.g., organic clay), and a leveling agent at an appropriate ratio, as needed. The hard coat composition can be diluted with a known solvent.

As will be described later in detail, to form a hard coat layer, a diluent of the hard coat composition is applied to one surface of the transparent substrate 41 in the thickness direction, heated as needed, and then dried. After drying, the hard coat composition is cured by, for example, irradiation with an active energy ray.

In this manner, a hard coat layer is formed.

The hard coat layer has a thickness of, for example, 0.1 μm or more, preferably 0.5 μm or more, more preferably 1 μm or more, and for example, 20 μm or less, preferably 10 μm or less, more preferably 5 μm or less.

### <Transparent Conductive Layer>

The transparent conductive layer 3 is disposed on one side of the substrate layer 2 in the thickness direction. To be specific, the transparent conductive layer 3 is in contact with the entire surface of the substrate first main surface 21 of the substrate layer 2. The transparent conductive layer 3 has a predetermined thickness, preferably includes a region of a single layer extending in the plane direction orthogonal to the thickness direction, more preferably is a single layer extending in the plane direction orthogonal to the thickness direction. To be specific, preferably, the transparent conductive layer 3 includes a region without a plurality of layers laminated in the thickness direction, more preferably the transparent conductive layer 3 does not include a plurality of layers laminated in the thickness direction. More specifically, a plurality of transparent conductive layers partitioned along the plane direction, preferably, a plurality of transparent conductive layers including boundaries parallel to the first main surface 21 of the substrate layer 2, are not included in the transparent conductive layer of the present invention.

The transparent conductive layer 3 includes a first main surface 5 and a second main surface 6 that are opposed to each other in the thickness direction.

The first main surface 5 is exposed on one side in the thickness direction. The first main surface 5 is a flat surface.

The second main surface 6 is opposed at a spaced interval to the first main surface 5 on the other side in the thickness direction. The second main surface 6 is a flat surface parallel to the first main surface 21. In one embodiment, the second main surface 6 is in contact with the substrate first main surface 21.

The flat surface may or may not include whether the first main surface 5 and the second main surface 6 are planes substantially in parallel to each other. For example, unevenness and waving that are too fine to be observed are allowed.

As shown in FIG. 2, a side surface 55 connects a peripheral end edge of the first main surface 5 and a peripheral end edge of the second main surface 6. The side surface 55 has one side surface 56 connecting one end edge of the first main surface 5 and one end edge of the second main surface 6, and the other side surface (not shown) connecting the other end edge of the first main surface 5 and the other end edge of the second main surface 6, in a cross-sectional view.

This transparent conductive layer 3 is crystalline. Preferably, the transparent conductive layer 3 does not include an amorphous region but only includes a crystalline region, in the plane direction. A transparent conductive layer including an amorphous region is identified by, for example, observing crystal grains in the plane direction of the transparent conductive layer with a TEM.

When the transparent conductive layer 3 is crystalline, for example, the transparent conductive layer 3 is immersed in 5 mass percent aqueous hydrochloric acid for 15 minutes, then rinsed with water and dried, and a resistance between two terminals at an interval of about 15 mm is measured on the first main surface 5 and is found to be 10 kΩ or less. Meanwhile, when the above-mentioned resistance between two terminals exceeds 10 kΩ, the transparent conductive layer 3 is amorphous.

The transparent conductive layer 3 has a plurality of crystal grains 4. The crystal grains 4 may be referred to as grains. The crystal grains 4 include a first crystal grain 31 partitioned by a first grain boundary 7 as an example of grain boundaries.

The first crystal grain 31 does not face the second main surface 6 or the side surface 55 but the first main surface 5. That is, the first crystal grain 31 faces only the first main surface 5.

The first grain boundary 7 includes two end edges 23. The first grain boundary 7 is opened to the first main surface 5. In the first grain boundary 7, an intermediate region 25 between the end edges 23 is not in contact with the second main surface 6 and the side surface 55. The first grain boundary 7 has a substantially U-shape opened toward one side in the thickness direction in a cross-sectional view. The first grain boundary 7 has a path going from one end edge 23 toward the other side in the thickness direction, then going in a width direction (an example of the direction orthogonal to the thickness direction) at a midway in the thickness direction, and subsequently returning to the other end edge 23 toward one surface side in the thickness direction. The first grain boundary 7 may have a path going from one end edge 23 toward the other side in the thickness direction, then turning back at a midway in the thickness direction, and subsequently returning to the other end edge 23 toward one surface side in the thickness direction.

Although not shown, a plurality of first crystal grains 31 may be provided in the transparent conductive layer 3. In this case, the end edges 23 adjacent to each other in the transparent conductive layer 3 may be common.

In this embodiment, the intermediate region 25 of the first grain boundary 7 includes a first branch point 26 and a second branch point 27.

Starting from the first branch point 26, a second grain boundary 8 is branched from the first grain boundary 7. The second grain boundary 8 has one end edge included in the intermediate region 25 and the other end edge opened to one side surface 56 (side surface 55). Then, the second grain boundary 8 and the portion extending from one end edge 23 to the midway of the intermediate region 25 in the first grain boundary 7 partition off a second crystal grain 32.

The second crystal grain 32 does not face the second main surface 6 but the first main surface 5 and one side surface 56. That is, the second crystal grain 32 faces only the first main surface 5 and one side surface 56.

Starting from the second branch point 27, a third grain boundary 9 is branched from the first grain boundary 7. The third grain boundary 9 has one end edge included in the intermediate region 25 and the other end edge opened to the second main surface 6. Then, the third grain boundary 9, the intermediate region 25 of the first grain boundary 7, and the second grain boundary 8 partition off a third crystal grain 33.

The third crystal grain 33 does not face the first main surface 5 but the second main surface 6 and one side surface 56. That is, the second crystal grain 32 faces only the second main surface 6 and one side surface 56.

The transparent conductive layer 3 can include a fourth crystal grain 44 that faces both the first main surface 5 and the second main surface 6.

The transparent conductive layer 3 may be a crystalline layer containing the first crystal grain 31, and the ratio of the first crystal grain 31 and the other crystal grain such as the second crystal grain 32, the third crystal grain 33, and the fourth crystal grain 44 present therein is arbitrary.

The first grain boundary 7, the second grain boundary 8, and the third grain boundary can be formed by, for example, adjusting temperature of the substrate layer 2 during sputtering, atmospheric pressure during film deposition, magnetic field strength on a target surface, and thickness of the transparent conductive layer 3.

The transparent conductive layer 3 contains a material and a trace amount of rare gas atoms having a higher atomic number than argon atoms (hereinafter referred to as first rare gas atoms). The transparent conductive layer 3 is preferably made of a material and a trace amount of first rare gas atoms. To be specific, the transparent conductive layer 3 has a trace amount of first rare gas atoms present in the material matrix.

The material is not particularly limited. Examples of the material include metal oxides containing at least one kind of metal selected from the group consisting of In, Sn, Zn, Ga, Sb, Nb, Ti, Si, Zr, Mg, Al, Au, Ag, Cu, Pd, and W.

Specific examples of the metal oxide include a tin-containing oxide, an indium zinc composite oxide (IZO), an indium gallium zinc composite oxide (IGZO), and an indium gallium composite oxide (IGO). Examples of the tin-containing oxide include an indium tin composite oxide (ITO) and an antimony tin composite oxide (ATO). As the metal oxide, preferably, a tin-containing oxide is used. When the material is a tin-containing oxide, it is excellent in transparency and electrical conductivity.

The content of tin oxide (SnO₂) in the transparent conductive layer 3 (tin-containing oxide) is not particularly limited and is, for example, 0.5% by mass or more, preferably 3% by mass or more, more preferably 6% by mass or more, and for example, less than 50% by mass, preferably 25% by mass or less, more preferably 15% by mass or less.

Examples of the first rare gas atoms include krypton atoms and xenon atoms, and preferably, krypton atoms are used.

The first rare gas atoms are derived from a first rare gas as a sputtering gas to be described later. In other words, as will be described later in detail, the first rare gas atoms derived from the first rare gas (described later) as the sputtering gas in a sputtering method are incorporated into the transparent conductive layer 3.

The content of the first rare gas atoms in the transparent conductive layer 3 is, for example, 1.0 atomic % or less, more preferably 0.7 atomic % or less, even more preferably 0.5 atomic % or less, particularly preferably 0.3 atomic % or less, most preferably 0.2 atomic % or less, furthermore less than 0.1 atomic %, and for example, 0.0001 atomic % or more.

The content of the first rare gas atoms can be measured by, for example, Rutherford backscattering spectrometry. The presence of the first rare gas atoms can be confirmed by, for example, X-ray fluorescence analysis. In the transparent conductive layer 3, when the content of the first rare gas atoms is excessively low (to be specific, the content of the first rare gas atoms is less than a detection limit value (lower limit value) of Rutherford backscattering spectrometry, the content of the first rare gas atoms cannot be quantified by Rutherford backscattering spectrometry in some cases. In the present invention, however, even in such a case, when the presence of the first rare gas atoms is identified by X-ray fluorescence analysis, it is judged that the content of the first rare gas atoms is at least 0.0001 atomic % or more.

The transparent conductive layer 3 has a thickness of, for example, 40 nm or more, preferably 60 nm or more, more preferably 70 nm or more, even more preferably, in view of resistance to moisture permeability, 100 nm or more, particularly preferably 120 nm or more, most preferably 140 nm or more, and in view of thinning, for example, 1000 nm or less, preferably 500 nm or less, more preferably less than 300 nm, even more preferably 200 nm or less, particularly preferably less than 150 nm, most preferably 148 nm or less. A method of determining the thickness of the transparent conductive layer 3 will be described in detail in Example below.

The ratio of a length between two end edges 23 in a cross-sectional view (an average length when there are a plurality of first crystal grains 31) to the thickness of the transparent conductive layer 3 is, for example, 0.1 or more, preferably 0.25 or more, and for example, 20 or less, preferably 10 or less, more preferably 5 or less, even more preferably 3 or less. When the above-mentioned ratio is above the lower limit and below the upper limit, the etching rate of the transparent conductive layer 3 can be increased.

The maximum crystal grain size of the plurality of crystal grains 4 is not particularly limited, and is, for example, 500 nm or less, preferably 400 nm or less, more preferably 350 nm or less, even more preferably 300 nm or less, particularly preferably 250 nm or less, most preferably 200 nm or less, and for example, 1 nm or more, preferably 10 nm or more. When the maximum crystal grain size of the plurality of crystal grains 4 is the upper limit or less, the amount of the first grain boundary 7 in a unit area on the first main surface 5 of the transparent conductive layer 3 can be increased, and therefore, the etching rate can be increased.

The transparent conductive layer 3 has a surface resistance of, for example, 200 Ω/square or less, preferably 50 Ω/square or less, more preferably 30 Ω/square or less, even more preferably 20 Ω/square or less, particularly preferably 15 Ω/square or less, and for example, more than 0 Ω/square.

The transparent conductive layer 3 has a specific resistance value of, for example, 2.2×10⁴ Ω·cm or less, preferably 1.8×10⁴ Ω·cm or less, more preferably 1.6×10⁴ Ω·cm or less, even more preferably 1.0×10⁴ Ω·cm or less. The above-mentioned specific resistance value is, for example, 0.1×10⁴ Ω·cm or more, preferably 0.5×10⁴ Ω·cm or more, more preferably 1.0×10⁴ Ω·cm or more, even more preferably 1.01×10⁴ Ω·cm or more. The specific resistance value can be determined by multiplying the thickness and surface resistance value of the transparent conductive layer 3.

### <Method for Producing Transparent Conductive Layer and Transparent Conductive Sheet>

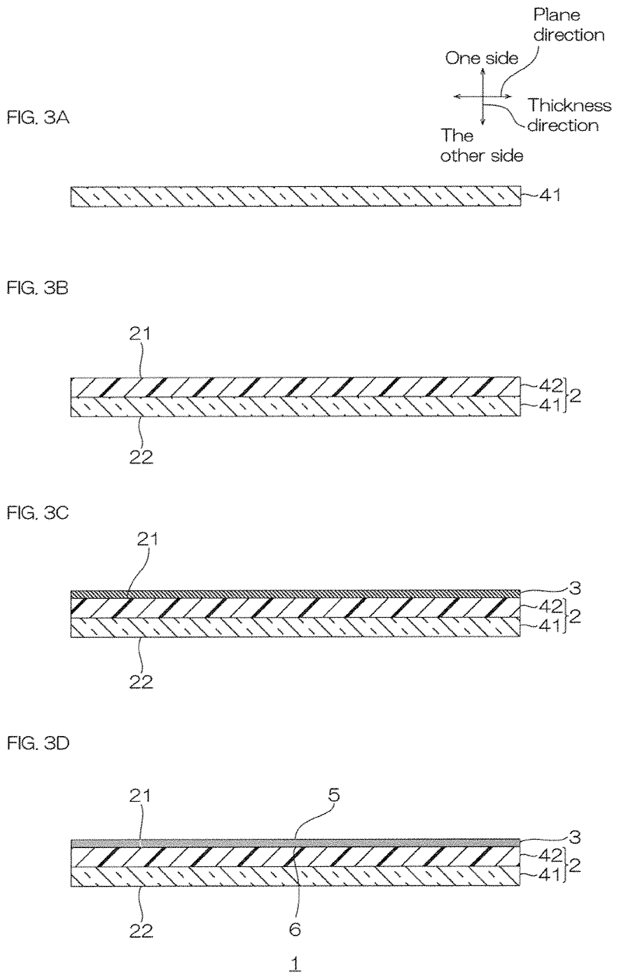

A method for producing the transparent conductive layer 3 and the transparent conductive sheet 1 will be described with reference to FIG. 3.

The method for producing the transparent conductive layer 3 and the transparent conductive sheet 1 includes a first step of preparing the substrate layer 2; a second step of disposing the transparent conductive layer 3 on one surface of the substrate layer 2 in the thickness direction; and a third step of heating the transparent conductive layer 3. In this method, the layers are sequentially disposed by, for example, a roll-to-roll system.

### <First Step>

In the first step, the substrate layer 2 is prepared.

To prepare the substrate layer 2, as shown in FIG. 3A, first, the transparent substrate 3 is prepared.

Next, as shown in FIG. 3B, a diluent of a hard coat composition is applied to one surface of the transparent substrate 41 in the thickness direction and dried, followed by ultraviolet irradiation or heating, whereby the hard coat composition is cured. In this manner, a hard coat layer (functional layer 42) is formed on one surface of the transparent substrate 41 in the thickness direction. Thus, the substrate layer 2 is prepared.

### <Second Step>

In the second step, as shown in FIG. 3C, the transparent conductive layer 3 is disposed on one surface of the substrate layer 2 in the thickness direction.

To be specific, a target made of the material of the transparent conductive layer 3 is sputtered in the presence of a sputtering gas in a sputtering apparatus while being opposed to one surface of the substrate layer 2 in the thickness direction. During sputtering, the substrate layer 2 is in close contact along a circumferential direction of a film deposition roll. At this time, in addition to the sputtering gas, for example, a reactive gas (e.g., oxygen) can also be allowed to be present.

The sputtering gas is a rare gas having a higher atomic number than argon atoms (hereinafter referred to as a first rare gas). Examples of the first rare gas include krypton gas and xenon gas, and preferably, krypton gas is used.

The sputtering gas in the sputtering apparatus has a partial pressure of, for example, 0.05 Pa or more, preferably 0.1 Pa or more, and for example, 10 Pa or less, preferably 5 Pa or less, more preferably 1 Pa or less.

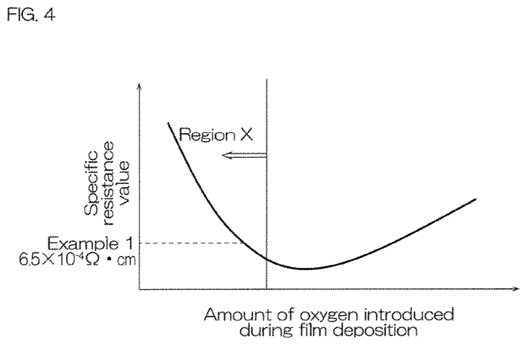

As shown in FIG. 4, the amount of the reactive gas introduced can be estimated by the surface resistance of the transparent conductive layer 3 that is amorphous. Specifically, since the film quality (surface resistance) of the amorphous transparent conductive layer 3 varies depending on the amount of the reactive gas introduced into the amorphous transparent conductive layer 3, the amount of the reactive gas introduced can be adjusted according to the surface resistance of the target amorphous transparent conductive layer 3. To obtain a transparent conductive layer 3 of a crystalline film by heating the amorphous transparent conductive layer 3, the amount of the reactive gas introduced may be adjusted within a range of a region X in FIG. 4, to obtain an amorphous transparent conductive layer 3.

To be specific, the reactive gas is introduced so that the amorphous transparent conductive layer 3 has a specific resistance of, for example, 8.0×10⁴ Ω·cm or less, preferably 7.0×10⁻⁴ Ω·cm or less, and for example, 2.0×10⁴ Ω·cm, preferably 4.0×10⁴ Ω·cm or more, more preferably 5.0×10⁻⁴ Ω·cm or more.

The pressure in the sputtering apparatus is substantially the sum of the partial pressure of the sputtering gas and the partial pressure of the reactive gas.

The power source may be any of, for example, a DC power source, an AC power source, an MF power source, and an RF power source. These may be used in combination.

A discharge output value relative to the long side of the target is, for example, 0.1 W/mm or more, preferably 0.5 W/mm, more preferably 1 W/mm or more, even more preferably 5 W/mm or more, and for example, 30 W/mm or less, preferably 15 W/mm or less. The direction of the long side of the target is, for example, a direction (TD direction) orthogonal to a feeding direction in the roll-to-roll type sputtering apparatus.

The target has a horizontal magnetic field strength of, for example, 10 mT or more, preferably 60 mT or more, and for example, 300 mT or less, on its surface. By setting the horizontal magnetic field strength on the surface of the target within the above-mentioned range, the amount of the first rare gas atoms in the transparent conductive layer 3 can be reduced, and thus, the transparent conductive layer 3 excellent in low resistivity can be produced.

Then, the material of the transparent conductive layer 3 that has been sprung out from the target by sputtering is deposited on the substrate layer 2. At this time, thermal energy generates, so that the transparent conductive layer 3 is preferably cooled through cooling of the substrate layer 2 with the film deposition roll during film deposition of the transparent conductive layer 3, and thus, crystallization of the transparent conductive layer 3 is suppressed.

Specifically, the temperature of the film deposition roll (furthermore, the temperature of the substrate layer 2) is, for example, −50° C. or more, preferably −20° C. or more, more preferably −10° C. or more, and for example, 30° C. or less, preferably 20° C. or less, more preferably 15° C. or less, even more preferably 10° C. or less, particularly preferably 5° C. or less. When the temperature is within the above range, the substrate 2 can be sufficiently cooled to allow crystal growth during film deposition of the transparent conductive layer 3 (in particular, crystal growth in the thickness direction of the transparent conductive layer 3) to be suppressed. Therefore, the first crystal grain is easily obtained in the transparent conductive layer 3 after the third step to be described later.

In this manner, the amorphous transparent conductive layer 3 is disposed on one surface of the substrate layer 2 in the thickness direction.

As described above, since the first rare gas is used as the sputtering gas, the first rare gas atoms derived from the first rare gas are incorporated into the transparent conductive layer 3.

### <Third Step>

In the third step, the amorphous transparent conductive layer 3 is heated. For example, using a heating device (e.g., an infrared heater, and a hot-air oven), the amorphous transparent conductive layer 3 is heated.

The heating temperature is, for example, 80° C. or more, preferably 110° C. or more, and for example, less than 200° C., preferably 180° C. or less. The heating time is, for example, 1 minute or more, preferably 10 minutes or more, more preferably 30 minutes or more, and for example, 24 hours or less, preferably 4 hours or less, more preferably 2 hours or less.

In this manner, as shown in FIG. 3D, the amorphous transparent conductive layer 3 is crystallized to form a crystalline transparent conductive layer 3.

Thus, the transparent conductive layer 3 is obtained, and a transparent conductive sheet 1 sequentially including the substrate layer 2 and the transparent conductive layer 3 is obtained.

Thereafter, the transparent conductive layer 3 can also be patterned. The patterning is performed by, for example, etching.

The patterning of the transparent conductive layer 3 gives a pattern shape to the transparent conductive layer 3. When the transparent conductive layer 3 has a pattern shape, the pattern shape can be freely designed.

<Article with Transparent Conductive Sheet and Article with Transparent Conductive Layer>

An article with the transparent conductive sheet can also be obtained by disposing the transparent conductive sheet 1 on one surface of a component in the thickness direction.

The article with the transparent conductive sheet sequentially includes the component and the transparent conductive sheet 1 toward one side in the thickness direction. Specifically, the article with the transparent conductive sheet sequentially includes the component, the substrate layer 2, and the transparent conductive layer 3 toward one side in the thickness direction.

The article is not particularly limited, and examples thereof include an element, a member, and a device. To be more specific, examples of the element include a light control element and a photoelectric conversion element. Examples of the light control element include a current driven-type light control element and an electric field driven-type light control element. Examples of the current driven-type light control element include an electrochromic (EC) light control element. Examples of the electric field driven-type light control element include a polymer dispersed liquid crystal (PDLC) light control element, a polymer network liquid crystal (PNLC) light control element, and a suspended particle device (SPD) light control element. Example of the photoelectric conversion element include a solar cell. Examples of the solar cell include an organic thin film solar cell, a perovskite solar cell, and a dye-sensitized solar cell. Examples of the member include an electromagnetic wave shielding member, a hot wire control member, a heater member, lighting, and an antenna member. Examples of the device include a touch sensor device and an image display device.

The article with the transparent conductive sheet is obtained by, for example, bonding the component and the substrate layer 2 of the transparent conductive sheet 1 with a fixing functional layer interposed therebetween.

Examples of the fixing functional layer include an adhesive layer and a bonding layer.

As a material of the fixing functional layer, any material can be used without particular limitation as long as it has transparency. The fixing functional layer is preferably formed of resin. Examples of the resin include acrylic resin, silicone resin, polyester resin, polyurethane resin, polyamide resin, polyvinyl ether resin, vinyl acetate/vinyl chloride copolymer, modified polyolefin resin, epoxy resin, fluorine resin, natural rubber, and synthetic rubber. In particular, in view of being excellent in optical transparency, exhibiting adhesive properties such as moderate wettability, cohesiveness, and tackiness, and also being excellent in weather resistance, heat resistance, and the like, acrylic resin is preferably selected as the resin.

In order to inhibit corrosion and migration of the transparent conductive layer 3, a known corrosion inhibitor and a migration inhibitor (e.g., material disclosed in Japanese Unexamined Patent Publication No. 2015-022397) can also be added to the fixing functional layer (fixing functional layer forming resin). Further, in order to suppress deterioration of the article with the transparent conductive sheet when used outdoors, a known ultraviolet absorber may be added to the fixing functional layer (fixing functional layer forming resin). Examples of the ultraviolet absorber include a benzophenone compound, a benzotriazole compound, a salicylic acid compound, an anilide oxalate compound, a cyanoacrylate compound, and a triazine compound.

A cover layer can also be disposed on the upper surface of the transparent conductive layer 3 in the article with the transparent conductive sheet.

The cover layer is a layer that covers the transparent conductive layer 3, and is capable of improving reliability of the transparent conductive layer 3 and suppressing functional deterioration due to scratching.

The cover layer is preferably a dielectric. The cover layer is formed from a mixture of a resin and an inorganic material. Examples of the resin include those exemplified in the fixing functional layer. The inorganic material is made of a composition containing inorganic oxide such as silicon oxide, titanium oxide, niobium oxide, aluminum oxide, zirconium dioxide, or calcium oxide, and fluoride such as magnesium fluoride.

From a viewpoint similar to that of the above-mentioned fixing functional layer, a corrosion inhibitor, a migration inhibitor, and an ultraviolet absorber can also be added to the cover layer (mixture of the resin and the inorganic material).

The article with the transparent conductive sheet can also be obtained by bonding the component and the transparent conductive layer 3 of the transparent conductive sheet 1 with the fixing functional layer interposed therebetween.

An article with the transparent conductive layer can also be obtained by disposing the transparent conductive sheet 3 on one surface of a component in the thickness direction.

The article with the transparent conductive layer sequentially includes the component and the transparent conductive layer 3 toward one side in the thickness direction.

The article with the transparent conductive layer is obtained by disposing the transparent conductive layer 3 on one surface of the component in the thickness direction by a sputtering method, or by transferring the transparent conductive layer 3 from the transparent conductive sheet 1 to one surface of the component in the thickness direction.

The component and the transparent conductive layer 3 can also be bonded with the above-mentioned fixing functional layer interposed therebetween.

A cover layer can also be disposed on the upper surface of the transparent conductive layer 3 in the article with the transparent conductive layer.

### <Operations and Effects of One Embodiment>

In the transparent conductive layer 3, when an etchant comes in contact with the first main surface 5, the etchant easily penetrates into the first grain boundary 7 from two end edges 23. Therefore, the first crystal grain 31 partitioned by the first grain boundary 7 is easily etched. To be specific, both the end edges 23 of the first grain boundary 7 that partitions the first crystal grain 31 face the first main surface 5, and therefore, when the etchant penetrates into the first grain boundary 7, the etchants from both the end edges 23 are joined in the intermediate region 25. For example, the first crystal grain 31 is not supported on the third crystal grain 33 facing the second main surface 6, and is thus easily etched (including lacking and falling off) from the transparent conductive layer 3. As a result of this, the etching rate of the transparent conductive layer 3 is high in the transparent conductive sheet 1.

In the transparent conductive layer 3, when an etchant comes in contact with one side surface 56, the etchant easily penetrates into the second grain boundary 8. Therefore, the second crystal grain 32 partitioned by the second grain boundary 8 is easily peeled off. As a result of this, the etching rate of the transparent conductive layer 3 is higher in the transparent conductive sheet 1.

Meanwhile, when the transparent conductive layer 3 has the first grain boundary 7 and the first crystal grain 31, the specific resistance thereof tends to increase in view of carrier mobility.

However, the transparent conductive layer 3 contains atoms (first rare gas atoms) derived from a sputtering gas. Therefore, even though the transparent conductive layer 3 has the first grain boundary 7 and the second grain boundary 8, the specific resistance of the transparent conductive layer 3 can be reduced.

Specifically, when the transparent conductive layer 3 is produced by a sputtering method, the atoms derived from the sputtering gas are incorporated into the transparent conductive layer 3. The atoms derived from the sputtering gas inhibit crystallization of the transparent conductive layer 3. As a result of this, the specific resistance of the transparent conductive layer 3 increases.

Meanwhile, the transparent conductive layer 3 is obtained using a first rare gas as the sputtering gas. Since the first rare gas has a higher atomic weight than argon, incorporation of the atoms derived from the first rare gas (first rare gas atoms) into the transparent conductive layer 3 can be suppressed. That is, although the transparent conductive layer 3 contains the atoms derived from the first rare gas (first rare gas atoms), the amount thereof is suppressed as described above. Therefore, the first rare gas atoms can prevent crystallization of the transparent conductive layer 3 from being inhibited. As a result of this, the specific resistance of the transparent conductive layer 3 can be reduced.

As described above, the transparent conductive layer 3 allows the specific resistance to be reduced and achieves a high etching rate.

The transparent conductive sheet 1, a touch sensor, a light control element, a photoelectric conversion element, a hot wire control member, an antenna, an electromagnetic wave shielding member, and an image display device each including the transparent conductive layer 3 allow the specific resistance to be reduced and achieves a high etching rate.

### Modifications

In the following modifications, the same reference numerals are provided for members and steps corresponding to each of those in one embodiment described above, and their detailed description is omitted. The modifications also achieve operations and effects similar to those of one embodiment, unless otherwise specified. Further, one embodiment and a modification thereof can be appropriately combined.

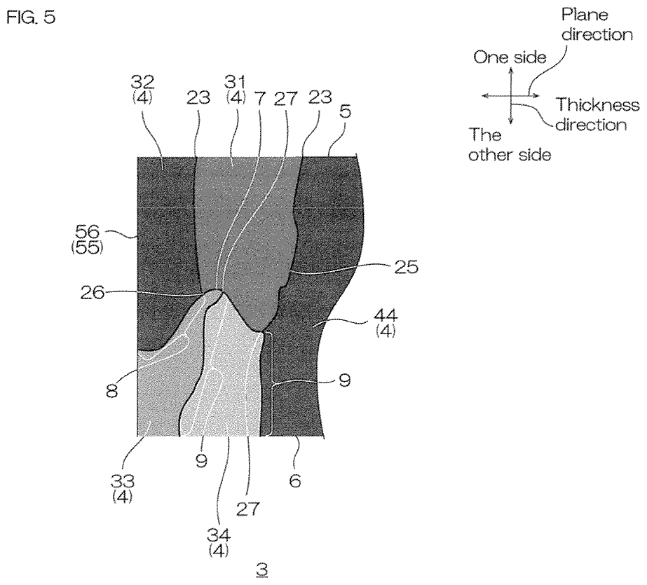

As shown in FIG. 5, the transparent conductive layer 3 can include a fourth crystal grain 34 that is partitioned by two third grain boundaries 9 each having the other end edge opened to the second main surface 6, and the intermediate region 25 of the first grain boundary 7. The intermediate region 25 includes two second branch points 27.

The fourth crystal grain 34 does not face one side surface 56 or the first main surface 5 but only the second main surface 6.

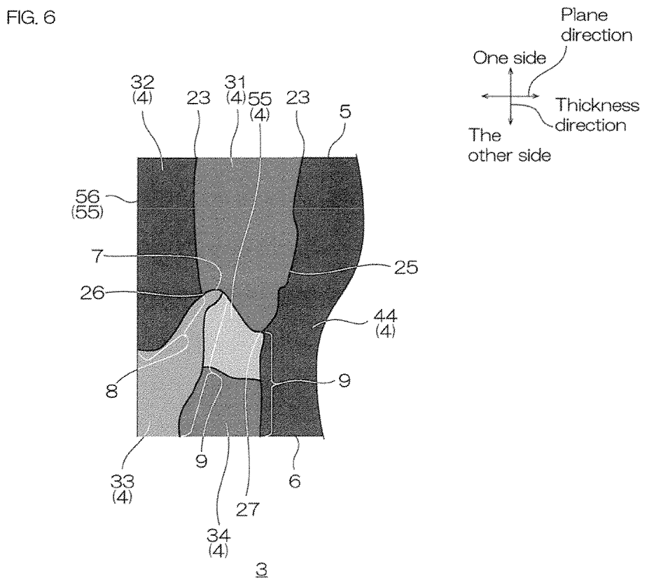

Further, as shown in FIG. 6, the transparent conductive layer 3 can include a fifth crystal grain 57 that does not face any of the first main surface 5, the second main surface 6, and the side surface 55.

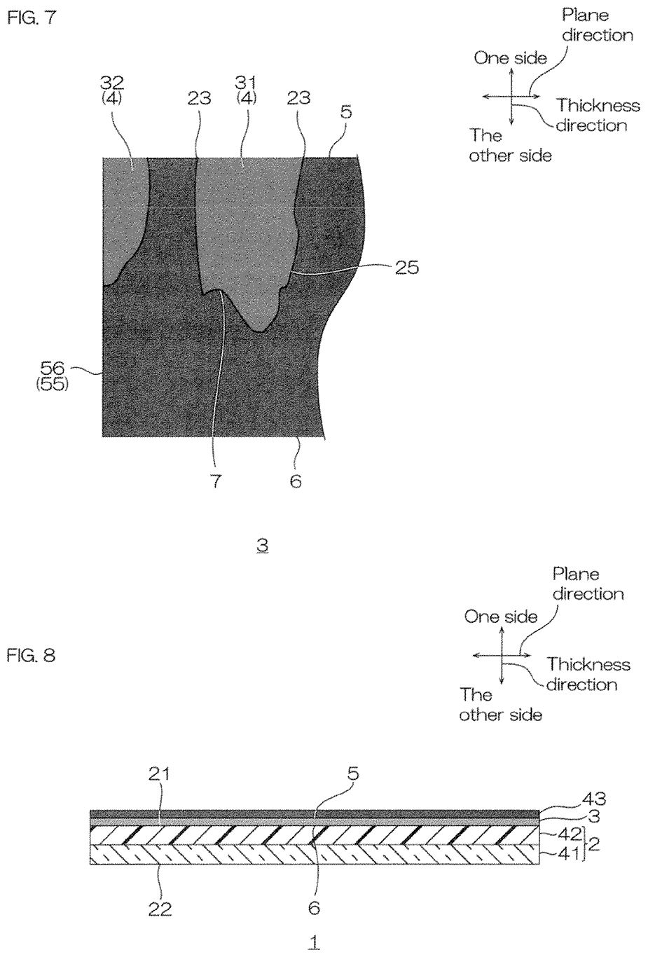

As shown in FIG. 7, the transparent conductive layer 3 does not have the above-mentioned third crystal grain 33 or fourth crystal grain 34 (see FIG. 2), that is, it has only the crystal grains 4 that do not face the second main surface 6. In this case, the intermediate region 25 does not include the first branch point 26 or second branch point 27 (see FIG. 2).

Preferably, as in one embodiment, the intermediate region 25 includes the second branch point 27, and the transparent conductive layer 3 includes the fourth crystal grain 34. This allows the etchant to penetrate from the second branch point 27 into the fourth crystal grain 34, and when the etchant reaches the second main surface 6, lacking of the fourth crystal grain 34 is accelerated. Therefore, the etching rate can be further increased.

In the above description, the transparent conductive sheet 1 sequentially includes the substrate layer 2, and the transparent conductive layer 3 toward one side in the thickness direction. In this transparent conductive sheet 1, the transparent conductive layer 3 contains first rare gas atoms.

Meanwhile, the transparent conductive sheet 1 can further include a transparent conductive layer not containing first rare gas atoms (hereinafter referred to as a first rare gas atom-free transparent conductive layer 43).

To be specific, as shown in FIG. 8, the transparent conductive sheet 1 sequentially includes the substrate layer 2, the transparent conductive layer 3, and the first rare gas atom-free transparent conductive layer 43 toward one side in the thickness direction. To be more specific, the transparent conductive sheet 1 includes the substrate layer 2, and the transparent conductive layer 3 disposed on one surface of the substrate layer 2 in the thickness direction, and the first rare gas atom-free transparent conductive layer 43 disposed on one surface of the transparent conductive layer 3 in the thickness direction.

The first rare gas atom-free transparent conductive layer 43 does not contain first rare gas atoms, but contains the above-mentioned material (specifically, similar to the material contained in the transparent conductive layer 3), a trace amount of rare gas atoms having an atomic number equal to or lower than argon atoms (hereinafter referred to as second rare gas atoms). The first rare gas atom-free transparent conductive layer 43 is preferably made of the above-mentioned material and a trace amount of second rare gas atoms. To be specific, in the first rare gas atom-free transparent conductive layer 43, a trace amount of second rare gas atoms are present in the above-mentioned material matrix.

Examples of the second rare gas atoms include argon atoms, neon atoms, and helium atoms, and preferably, argon atoms are used.

The second rare gas atoms are derived from a second rare gas as a sputtering gas to be described later. In other words, as will be described later in detail, the second rare gas atoms derived from the second gas (described later) as the sputtering gas in the sputtering method are incorporated into the first rare gas atom-free transparent conductive layer 43.

Since the second rare gas atoms have a lower atomic weight than the first rare gas atoms, the content of the second rare gas atoms in the transparent conductive layer 3 is larger than that of the first rare gas atoms. Therefore, the content of the second rare gas atoms in the first rare gas atom-free transparent conductive layer 43 is specifically 2.0 atomic % or less, preferably 1.0 atomic % or less, more preferably 0.7 atomic % or less, particularly preferably 0.5 atomic % or less, most preferably 0.3 atomic % or less, furthermore 0.2 atomic % or less, and for example, 0.0001 atomic % or more.

The method of confirming the content of the second rare gas atoms and the method of confirming the presence of the second rare gas atoms are the same as the above-mentioned methods for the first rare gas atoms.

The first rare gas atom-free transparent conductive layer 43 has a thickness of, for example, 1 nm or more, preferably 10 nm or more, more preferably 30 nm or more, even more preferably 70 nm or more, and for example, 500 nm or less, preferably less than 300 nm, more preferably 200 nm or less, even more preferably less than 150 nm, particularly preferably 100 nm or less. The method of determining the thickness of the first rare gas atom-free transparent conductive layer 43 is the same as the method of determining the thickness of the transparent conductive layer 3.

To dispose the first rare gas atom-free transparent conductive layer 43 on one surface of the transparent conductive layer 3 in the thickness direction, the transparent conductive layer 3 is disposed on one surface of the substrate layer 2 in the thickness direction in the above-mentioned second step, followed by disposing the first rare gas atom-free transparent conductive layer 43 on one surface of the transparent conductive layer 3 in the thickness direction.

To be specific, a target made of the material of the first rare gas atom-free transparent conductive layer 43 is sputtered in the presence of a sputtering gas in a sputtering apparatus while being opposed to one surface of the transparent conductive layer 3 in the thickness direction. During sputtering, the transparent conductive layer 3 (specifically, substrate layer 2 including the transparent conductive layer 3) is in close contact along a circumferential direction of a film deposition roll. At this time, in addition to the sputtering gas, for example, a reactive gas (e.g., oxygen) can also be allowed to be present.

The sputtering gas is a rare gas having an atomic number equal to or lower than argon atoms (hereinafter referred to as a second rare gas). Examples of the second rare gas include argon gas, neon gas and helium gas, and preferably, argon gas is used.

The partial pressure of the sputtering gas in the sputtering apparatus, the amount of the reactive gas introduced, the power source, and the discharge output value relative to the long side of the target are the same as the sputtering conditions when the above-mentioned transparent conductive layer 3 is disposed.

Then, the material of the first rare gas atom-free transparent conductive layer 43 that has been sprung out from the target by sputtering is deposited on the transparent conductive layer 3. At this time, thermal energy generates, so that the first rare gas atom-free transparent conductive layer 43 is cooled through cooling of the transparent conductive layer 3 with the film deposition roll during film deposition of the first rare gas atom-free transparent conductive layer 43, and thus, crystallization of the first rare gas atom-free transparent conductive layer 43 is suppressed.

Specifically, the temperature of the film deposition roll is the same as that during sputtering when the above-mentioned transparent conductive layer 3 is disposed.

In this manner, an amorphous first rare gas atom-free transparent conductive layer 43 is disposed on one surface of the transparent conductive layer 3 in the thickness direction.

As described above, since the second rare gas is used as the sputtering gas, the second rare gas atoms derived from the second rare gas is incorporated into the first rare gas atom-free transparent conductive layer 43.

Thus, the first rare gas atom-free transparent conductive layer 43 is obtained, and the transparent conductive sheet 1 sequentially including the substrate layer 2, the transparent conductive layer 3, and the first rare gas atom-free transparent conductive layer 43 is obtained.

In FIG. 8, the transparent conductive sheet 1 sequentially includes the substrate layer 2, the transparent conductive layer 3, and the first rare gas atom-free transparent conductive layer 43 toward one side in the thickness direction. Though not shown, the transparent conductive sheet 1 can also sequentially include the substrate layer 2, the first rare gas atom-free transparent conductive layer 43, and the transparent conductive layer 3 toward one side in the thickness direction.

In the above description, the case where the functional layer 42 is a hard coat layer has been described, but the functional layer 42 may be an optical adjustment layer.

The optical adjustment layer is a layer that adjusts optical properties (e.g., refractive index) of the transparent conductive sheet 1 so as to suppress visual recognition of a pattern in the transparent conductive layer 3, to suppress reflection at an interface in the transparent conductive sheet 1, and to ensure excellent transparency in the transparent conductive sheet 1.

The optical adjustment layer is formed of, for example, an optical adjustment composition.

The optical adjustment composition contains, for example, a resin and particles. Examples of the resin include those exemplified in the above-mentioned hard coat composition. Examples of the particles include those exemplified in the above-mentioned hard coat composition. The optical adjustment composition may be a resin alone or an inorganic material alone. Examples of the resin include those exemplified in the above-mentioned hard coat composition. Examples of the inorganic material include metalloid oxides and/or metal oxides such as silicon oxide, alumina, titania, zirconia, calcium oxide, tin oxide, indium oxide, cadmium oxide, and antimony oxide. The metalloid oxide and/or metal oxide may or may not be a stoichiometric composition.

The optical adjustment layer has a thickness of, for example, 1 nm or more, preferably 5 nm or more, more preferably 10 nm or more, and for example, 200 nm or less, preferably 100 nm or less. The thickness of the optical adjustment layer can be calculated based on, for example, wavelength of the interference spectrum observed using an instantaneous multi-photometric system. The thickness thereof may be specified by observing the cross section of the optical adjustment layer by FE-TEM.

As the functional layer 42, the hard coat layer and the optical adjustment layer can also be used in combination (a multilayer including the hard coat layer and the optical adjustment layer).

In the above description, the substrate layer 2 sequentially includes the transparent substrate 41 and the functional layer 42 toward one side in the thickness direction. However, the substrate layer 2 can also be made of the transparent substrate 41 without including the functional layer 42.

In the above description, although the transparent conductive layer 3 contains a material and first rare gas atoms, it can also contain second rare gas atoms together with them.

When the transparent conductive layer 3 contains the second rare gas atoms, a second rare gas is used together with the first rare gas as the sputtering gas in the above-mentioned second step.

In this manner, the second rare gas atoms derived from the second rare gas are incorporated into the transparent conductive layer 3 together with the first rare gas atoms derived from the first rare gas.

The content of the second rare gas atoms is specifically 2.0 atomic % or less, preferably 1.0 atomic % or less, even more preferably 0.7 atomic % or less, particularly preferably 0.5 atomic % or less, most preferably 0.3 atomic % or less, furthermore 0.2 atomic % or less, and for example, 0.0001 atomic % or more.

As described above, the transparent conductive layer 3 can, but preferably does not, contain the second rare gas atoms. That is, the transparent conductive layer 3 is preferably made of a material and first rare gas atoms.

### EXAMPLE

In the following, the present invention is described in further detail with reference to Examples and Comparative Examples. The present invention is not limited to Examples and Comparative Examples in any way. The specific numeral values used in the description below, such as mixing ratios (ratios), physical property values, and parameters can be replaced with the corresponding mixing ratios (ratios), physical property values, and parameters in the above-described “DESCRIPTION OF THE EMBODIMENTS”, including the upper limit values (numeral values defined with “or less”, and “less than”) or the lower limit values (numeral values defined with “or more”, and “more than”).

### Example 1

### 1. Production of Transparent Conductive Layer and Transparent Conductive Sheet Example 1

### <First Step>

A coating of a hard coat composition (an ultraviolet curable resin containing acrylic resin) was applied to one surface of a long PET film (50 μm thick, manufactured by Toray Industries, Inc.) as a transparent substrate in the thickness direction to form a coated film. Subsequently, the coated film was cured by ultraviolet irradiation. This formed a hard coat layer (2 μm thick). In this manner, a substrate layer was prepared.

### <Second Step>

Next, an amorphous transparent conductive layer having a thickness of 150 nm was disposed on one surface of the substrate layer (hard coat layer) in the thickness direction by a reactive sputtering method. In the reactive sputtering method, a sputtering film deposition apparatus (DC magnetron sputtering apparatus) capable of conducting a film deposition process by a roll-to-roll system was used.

Specifically, as a target, a sintered body of indium oxide and tin oxide (with a tin oxide concentration of 10% by mass) was used. As a power source for applying a voltage to the target, a DC power source was used. A horizontal magnetic field strength on the target was 90 mT. In the sputtering apparatus, the substrate layer was brought into close contact with a film deposition roll along the circumferential direction thereof. The temperature of the film deposition roll (temperature of the substrate layer) was −8° C. A sputtering film deposition apparatus was vacuum-evacuated until an ultimate degree of vacuum in a sputtering film deposition chamber included in the sputtering film deposition apparatus reached 0.8×10⁻⁴ Pa, and krypton as a sputtering gas and oxygen as a reactive gas were then introduced into the sputtering film deposition apparatus, so that the atmospheric pressure in the sputtering film deposition apparatus was 0.2 Pa. A ratio of an amount of oxygen introduced with respect to the total amount of krypton and oxygen introduced into the sputtering film deposition apparatus was about 2.5 flow rate %. The amount of oxygen introduced was within a region X of a specific resistance-oxygen introduced amount curve as shown in FIG. 4, and was adjusted so that an amorphous transparent conductive layer had a specific resistance value of 6.5×10⁻⁴ Ω·cm. The specific resistance-oxygen introduced amount curve shown in FIG. 4 can be created by previously checking the dependence of the specific resistance of the amorphous transparent conductive layer on the amount of oxygen introduced when the amorphous transparent conductive layer is formed by the reactive sputtering method under the same conditions as above except the amount of oxygen introduced.

### <Third Step>

The amorphous transparent conductive layer was crystallized by heating in a hot-air oven. The heating temperature was 165° C. and the heating time was 1 hour.

In this manner, a transparent conductive layer was obtained, and a transparent conductive sheet sequentially including the substrate layer and the transparent conductive layer was obtained.

### Example 2

A transparent conductive layer and a transparent conductive sheet were produced by the same procedure as in Example 1.

However, the second step was changed as follows.

### <Second Step>

An amorphous transparent conductive layer having a thickness of 50 nm was disposed on one surface of the substrate layer (hard coat layer) in the thickness direction by a reactive sputtering method. In the reactive sputtering method, a sputtering film deposition apparatus (DC magnetron sputtering apparatus) capable of conducting a film deposition process by a roll-to-roll system was used.

Specifically, as a target, a sintered body of indium oxide and tin oxide (with a tin oxide concentration of 10% by mass) was used. As a power source for applying a voltage to the target, a DC power source was used. A horizontal magnetic field strength on the target was 90 mT. The film deposition temperature was −5° C. The sputtering film deposition apparatus was vacuum-evacuated until an ultimate degree of vacuum in the sputtering film deposition chamber included in the sputtering film deposition apparatus reached 0.8×10⁻⁴ Pa, and krypton as a sputtering gas and oxygen as a reactive gas were then introduced into the sputtering film deposition apparatus, so that the atmospheric pressure in the film deposition chamber was 0.2 Pa. The amount of oxygen introduced into the film deposition chamber was adjusted so that a formed film had a specific resistance value of 6.5×10⁻⁴ Ω·cm.

Next, an amorphous first rare gas atom-free transparent conductive layer 43 having a thickness of 80 nm was disposed on one surface of the transparent conductive layer in the thickness direction by a reactive sputtering method.

The conditions of the reactive sputtering method are the same as those used when the amorphous transparent conductive layer was disposed on one surface of the substrate layer (hard coat layer) in the thickness direction by the above-mentioned reactive sputtering method.

However, the sputtering gas was changed to argon gas. The atmospheric pressure in the film deposition chamber after the sputtering gas and oxygen as the reactive gas were introduced was changed to 0.4 Pa.

In this manner, a transparent conductive layer was obtained, and a transparent conductive sheet sequentially including the substrate layer, the transparent conductive layer (50 nm thick), and the first rare gas atom-free transparent conductive layer (80 nm thick) was obtained.

### Example 3

A transparent conductive film was obtained together with a transparent conductive layer, in the same manner as in Example 1.

However, in the second step, the sputtering gas was changed to a gas mixture of krypton and argon (90% by volume of krypton, 10% by volume of argon).

### Comparative Example 1

A transparent conductive sheet was obtained together with a transparent conductive layer, in the same manner as in Example 1.

However, in the second step, the sputtering gas was changed to argon gas. In the second step, the atmospheric pressure in the film deposition chamber after the sputtering gas and oxygen as the reactive gas were introduced was changed to 0.4 Pa.

### Comparative Example 2

A transparent conductive sheet was obtained together with a transparent conductive layer, in the same manner as in Example 1.

However, in the second step, the atmospheric pressure in the film deposition chamber after the sputtering gas and oxygen as the reactive gas were introduced was changed to 0.4 Pa. In the third step, the temperature of the film deposition roll (temperature of the substrate layer) was changed to 50° C. The thickness of the transparent conductive layer was changed to 30 nm.

### 2. Evaluation

### [Thickness of Transparent Conductive Layer]

The thickness of each of the transparent conductive layers in Examples 1 and 3 and Comparative Examples 1 and 2 was measured by FE-TEM observation (cross-section observation). To be specific, first, a sample for cross-section observation of each of the transparent conductive layers in Example 1 and Comparative Examples 1 and 2 was prepared by an FIB micro-sampling method. In the FIB micro-sampling method, an FIB device (trade name “FB2200” manufactured by Hitachi Ltd.) was used, and the accelerating voltage was set to 10 kV. Next, the thickness of the transparent conductive layer in the sample for cross-section observation was measured by FE-TEM observation. In the FE-TEM observation, an FE-TEM device (trade name “JEM-2800” manufactured by JEOL Ltd.) was used, and the accelerating voltage was set to 200 kV. Their thicknesses are shown in Table 1.

To measure the thickness of the transparent conductive layer in Example 2, a sample for cross-section observation was prepared from an intermediate prepared before the first rare gas atom-free transparent conductive layer was disposed on one surface of the transparent conductive layer in the thickness direction. The sample for cross-section observation was then measured by FE-TEM observation. In this manner, the thickness of the transparent conductive layer was measured. The thickness of the first rare gas atom-free transparent conductive layer was determined by measuring the total thickness of the transparent conductive layer and the first rare gas atom-free transparent conductive layer by FE-TEM observation, and then subtracting the thickness of the transparent conductive layer from the total thickness thereof

### [Confirmation of Krypton Atoms in Transparent Conductive Layer]

Whether each of the transparent conductive layers in Examples 1, 2, and 3 and Comparative Example 2 contained krypton atoms was confirmed as follows. First, using a scanning X-ray fluorescence spectrometer (trade name “ZSX Primus IV” manufactured by Rigaku Corporation), X-ray fluorescence analysis measurement was repeated 5 times under the following measurement conditions, an average value of the scan angles was calculated, and an X-ray spectrum was generated. It was then confirmed that a peak appeared near a scan angle of 28.2° in the generated X-ray spectrum, thereby confirming that krypton atoms were contained in the transparent conductive layer.

### <Measurement Conditions>

Spectrum: Kr-KA

Measurement diameter: 30 mm

Atmosphere: Vacuum

Target: Rh

Tube voltage: 50 kV

Tube current: 60 mA

Primary filter: Ni40

Scan angle (deg.): 27.0 to 29.5

Step (deg.): 0.020

Speed (deg/min): 0.75

Attenuator: 1/1

Slit: S2

Analyzing crystal: LiF (200)

Detector: SC

PHA: 100 to 300

### [Confirmation of Argon Atoms in Transparent Conductive Layer]

According to Rutherford backscattering spectrometry (RBS), it was confirmed that argon atoms were contained in the first rare gas atom-free transparent conductive layers of Examples 2 and 3 and the transparent conductive layer of Comparative Example 1. More specifically, four elements including In+Sn (in RBS, it was difficult to measure In and Sn separately, so that the two elements were evaluated in combination), O, and Ar were measured as detected elements, and the presence of the argon atoms in the light-transmitting electrically conductive layer was confirmed. The use device and the measurement conditions are as follows.

### <Use Device>

Pelletron 3SDH (manufactured by National Electrostatics Corporation)

### <Measurement Conditions>

Incident ion: 4He⁺⁺

Incident energy: 2300 keV

Incident angle: 0 deg.

Scattering angle: 160 deg.

Sample current: 6 nA

Beam diameter: 2 mmφ

In-plane rotation: Nil

Irradiation dose: 75 μC

### [Presence or Absence of First Grain Boundary, Second Grain Boundary, and First Crystal Grain]

The cross section of the transparent conductive sheet of each of Examples and Comparative Examples was adjusted by an FIB micro-sampling method, and the FE-TEM observation was then performed on the cross section of each of the transparent conductive layers to observe the presence or absence of the first grain boundary, the second grain boundary, and the first crystal grain. The magnification was set so that any of the crystal grains can be observed. Table 1 shows the presence or absence of the first grain boundary, the second grain boundary, and the first crystal grain.

In Example 1, Example 2, and Comparative Example 1, a second crystal grain, a third crystal grain, and a fourth crystal grain were observed together with the first grain boundary, the second grain boundary, and the first crystal grain.

The device and the measurement conditions are as follows.

FIB device: FB2200 manufactured by Hitachi Ltd., accelerating voltage: 10 kV
FE-TEM device: JEM-2800 manufactured by JEOL Ltd., accelerating voltage: 200 kV

### [Specific Resistance Value]

The surface resistance of each of the transparent conductive layers of Examples and Comparative Examples was measured by a four-terminal method. Then, the resulting surface resistance was multiplied by the thickness of the transparent conductive layer to determine a specific resistance value. The specific resistance value was evaluated based on the following criteria. The results are shown in Table 1.

Excellent: The specific resistance value was 1.6×10⁻⁴ Ω·cm or less.
Good: The specific resistance value was 1.7×10⁻⁴ Ω·cm or more and 2.2×10⁴ Ω·cm or less.
Bad: The specific resistance value was more than 2.2×10⁴ Ω·cm.

### [Etching Rate of Transparent Conductive Layer]

The transparent conductive sheet of each of Examples and Comparative Examples was immersed in hydrochloric acid having a concentration of 7% by mass at 35° C., then rinsed with water and dried, and a resistance between terminals at an interval of 15 mm was measured using a tester (the tester had a measurement cycle period of 15 seconds). In the present specification, when the resistance between terminals at an interval of 15 mm exceeded 50 kΩ after immersing in hydrochloric acid, rinsing with water, and drying, or when the terminals were insulated, such time was determined as a time when etching of the transparent conductive layer 3 was completed. Then, the time was divided by the total thickness of the transparent conductive layer to determine a time required for etching 1 nm of the transparent conductive layer (etching rate (s/nm)), and the time was evaluated according to the following criteria:

Excellent: The etching time per unit thickness was 12 (s/nm) or more to 20 (s/nm) or less.
Good: The etching time per unit thickness was less than 12 (s/nm).
Bad: The etching time per unit thickness was more than 20 (s/nm).

### [Table 1]

TABLE 1

| | Transparent conductive layer | | | | | | | | | | | |
|---|---|---|---|---|---|---|---|---|---|---|---|---|
| | | | | | Presence or | | | | | | | |
| | | | | | absence of | | | | | | | |
| | | | | | first grain | First rare gas atom-free | | | | | | |
| | | | | | boundary, | transparent conductive layer | | | | | Evaluation | |
| | Content | | | | second grain | Content | | | | Film | Specific | |
| Examples & | of tin | First | Thick- | | boundary, | of tin | Second | Thick- | | deposition | resis- | |
| Comparative | oxide | rare gas | ness | Film | and first | oxide | rare gas | ness | Film | pressure | tance | Etching |
| Examples | (mass %) | atom | (nm) | quality | crystal grain | (mass %) | atom | (nm) | quality | (Pa) | value | rate |
| Example 1 | 10 | Krypton | 150 | Crystalline | Presence | — | — | — | — | 0.2 | Excellent | Excellent |
| | | atom | | | | | | | | | | |
| Example 2 | 10 | Krypton | 50 | Crystalline | Presence | 10 | Argon | 80 | Crystalline | 0.2 | Excellent | Excellent |
| | | atom | | | | | atom | | | | | |
| Example 3 | 10 | Krypton | 150 | Crystalline | Presence | — | — | — | — | 0.2 | Excellent | Excellent |
| | | atom | | | | | | | | | | |
| Comparative | 10 | (Argon | 150 | Crystalline | Presence | — | — | — | — | 0.4 | Bad | Good |
| Example 1 | | atom) | | | | | | | | | | |
| Comparative | 10 | Krypton | 30 | Crystalline | Absence | — | — | — | — | 0.4 | Excellent | Bad |
| Example 2 | | atom | | | | | | | | | | |

While the illustrative embodiments of the present invention are provided in the above-described invention, such is for illustrative purpose only and it is not to be construed restrictively. Modification and variation of the present invention that will be obvious to those skilled in the art is to be covered by the following claims.

### INDUSTRIAL APPLICABILITY

The transparent conductive layer and the transparent conductive sheet according to the present invention is suitably used in, for example, an electromagnetic wave shielding member, a hot wire control member, a heater member, lighting, an antenna member, a touch sensor device, and an image display device.

### DESCRIPTION OF REFERENCE NUMERALS

1 transparent conductive sheet
2 substrate layer
3 transparent conductive layer
4 crystal grain
5 first main surface
6 second main surface
8 second grain boundary
9 end edge
25 intermediate region
31 first crystal grain
55 side surface
56 one side surface

1. A transparent conductive layer comprising
a first main surface; and a second main surface opposed to the first main surface in a thickness direction,
having a grain boundary in which two end edges in a cross-sectional view are both opened to the first main surface and an intermediate region between the end edges is not in contact with the second main surface; and
a first crystal grain partitioned by the grain boundary and facing only the first main surface, and
containing rare gas atoms having a higher atomic number than argon atoms.

2. The transparent conductive layer according to claim 1, comprising a region of a single layer extending in a plane direction orthogonal to the thickness direction.

3. The transparent conductive layer according to claim 1, further having a second grain boundary opened to a side surface that connects an end edge of the first main surface and an end edge of the second main surface.

4. The transparent conductive layer according to claim 1, wherein a material of the transparent conductive layer is a tin-containing oxide.

5. A transparent conductive sheet comprising:
a transparent conductive layer as defined in claim 1; and
a substrate layer located on a side of the second main surface of the transparent conductive layer.
